(19) United States
(12) Patent Application Publication
(10) Pub. No.: US 2007/0177426 A1
(43) Pub. Date: Aug. 2, 2007

(54) System and method for automated delivery of software payload

(76) Inventor: Richard Dellacona, Corona Del Mar, CA (US)

Correspondence Address: Don Carnegie, Suite 5A PMB540, 5405 Alton Parkway, Irvine, CA, 92604, US

(21) Appl. No.: 11/490,993

(22) Filed: Jul. 20, 2006

Related U.S. Application Data
(63) Continuation-in-part of application No. 11/377,751, filed on Mar. 16, 2006.
(60) Provisional application No. 60/763,629, filed on Jan. 31, 2006.

(51) Int. Cl. G11C 16/04

(52) U.S. Cl. 365/185.11

(57) ABSTRACT

The present invention discloses a system and method for delivery of software payload from a peripheral device to a host system, with generally one component of the software payload enabling the host system to communicate with the peripheral device. The method of the present invention uses an electronic component/storage device associated with the peripheral device (or provides one if none exists), and configures the electronic component to comprise a file system (e.g., CDFS—Compact Disk File System) and files that are native to operating system of the host (e.g., AUTORUN.INF), which the host system can recognize, access, and use automatically for initiating communications with the peripheral device, and delivery of the software payload. When communication with the host is established, any program can be loaded from the peripheral device to the host because the peripheral device appears to the host system as a CD ROM with an AUTORUN. INF file.

### CROSS-REFERENCES TO RELATED APPLICATIONS

The present application is a Continuation-in-Part of U.S. patent application Ser. No. 11/377,751, filed on Mar. 16, 2006, now pending, which claims the benefit of priority from related U.S. Provisional Patent Application Ser. No. 60/763,629, filed Jan. 31, 2006, the entire disclosures of both of which are incorporated by reference herein.

### BACKGROUND OF THE INVENTION

(1) Field of the Invention

This invention relates to delivery of software payload and, more particularly, to automated delivery of software without user intervention.

(2) Description of Related Art

In general, software that a host system uses to communicate with a device (internal or external) are typically known as device driver (or driver programs or device software). Most devices using conventional peripheral interface that use standard protocols for data transfer require a device driver, which allows for communication of the device with an operating system that resides within the host system. Non-limiting examples of peripheral interface that use standard protocols for communication and data transfer may include any popular industry standard links or ports that use cables, Universal Serial Bus (USB), parallel, fire wire, network, optical, wireless, or a combination thereof, etc.

Conventional driver software delivery methods have been in use for a number of years. Reference is made to the following exemplary U.S. Pat. Nos. 6,754,722; 6,728,787; 6,668,376; 6,567,860; 6,513,159; 6,473,854; 5,752,032; 5,723,282; 5,555,401; and 5,319,751; and U.S. Patent Application Publications 2005/0257218; 2005/0160157; 2005/0132090; 2005/0038927; 2004/0019896; 2004/0230988; 2004/0187105; 2003/0046674; 2002/0174085; and 2002/0095526. Regrettably, most conventional driver software delivery methods suffer from obvious disadvantages in terms of generally involving end-users in the activation and or loading of the driver software.

The process of installing a driver software is typically performed by the user loading the driver software package (device driver plus a device driver installation program) into a computer system from a removable delivery media (e.g., an optical/magnetic media such as CD-ROM, flash, etc.), and launching a device driver installation program. The device driver installation program is usually launched by an executable setup file that the operating system of the host retrieves and executes to commence the device driver installation program. For example, within the WINDOWS® operating system, this executable file is generally known as the “setup.exe.” The device driver installation program is generally comprised of Graphic User Interface (GUI) that aids the user in loading of the actual device driver. In other words, the device driver installation program generally includes GUI software with which the user interacts to update or change the various registers (settings or file systems) of the operating system to enable the host to communicate with the peripheral device. The use of removable delivery media for installing a driver software package requires shipping of the removable delivery media separately along with a device, which incurs additional cost. The cost of producing and shipping the driver software package can add to the overall cost of the device and, may in some cases, account for a significant fraction of the total cost for certain low cost devices, such as internal modems or scanners. Because it is separate from the peripheral device, the media can be easily misplaced by the user, making it difficult, and sometimes impossible, to reload the driver in the case where the manufacturer no longer supports the hardware, is out of business, or access to the internet driver database sites is not available. In these situations where the driver can not be reloaded, the peripheral becomes useless.

The driver software package may also be loaded and installed into a driver library of the operating system of the host computer, with the user manually selecting the driver software package from the driver library for launching the device driver installation program. However, this method of delivery provides a driver software package that is typically out-dated by the time it is installed. For example, the driver library in the operating system is the same age as the operating system. Hence, the driver software package in the driver library can potentially be many years old. Furthermore, if the device is new, a corresponding driver software package will not exist in the operating system's driver library.

Other delivery methods for installing driver software packages include the use of the network and the World Wide Web, which requires a user to have access to the Internet. This method of delivery requires user interaction with a device manufacturer website, which involves the process of downloading the driver software package therefrom, and the launch and interaction with the device driver installation program thereafter. In some instances, the host system is provided with a default driver that can act as an “interim” driver for the device in a restricted performance or mode until the user has access to the Internet and can download a current driver. However, this compounds the problem in that with the use of the Internet as a method for delivery of driver software, the manufacture of both a default driver as well as a current driver is required. In addition, with the default driver being shipped with the host system, within the host system driver library, the end users will encounter the same conventional problems mentioned above.

As is apparent from the prior art, conventional prior art installation processes and the medium of delivery for driver software are time-consuming and present a challenge for a novice computer user not familiar with the installation process. In addition, when the installation medium (e.g., CD, DVD, or other media, or access to the Internet) is needed in the future, and is unavailable, the device will not be able to communicate with the host system, and will be useless.

Regardless of the medium from which the device drivers are loaded within the host system, in most cases, the device driver packages include both the actual device driver and the device driver installation programs, which are supposed to aid the user in loading of the actual device driver. However, regrettably, the problem with most device driver installation programs is that (no matter how user friendly), they may interfere with an existing program, and may corrupt or disable existing programs, rendering them useless. Further, the interference of the device driver installation program with other programs may render the device useless. Generally the common admonition when loading any new software for a peripheral, an instruction is given to shut down all other programs before loading the desired software. The reason for this instruction is any software running may be using computer resources that the new software requires in order to load. If both programs need the same resource, there will be a conflict, with potential damage to the software.

More costly problems for the manufacturers of a device driver software packages in relation to the device driver installation programs is that different versions (e.g., GUI interface, etc.) of the installation programs must be provided for different operating systems and/or different computing/communications devices. For examples, using the present media system to install drivers requires the manufacturer to chose which Operating Systems for which to write drivers (e.g., WINDOWS®), and the type of host system (PDA, computer, mobile phone, etc.) that is used for communicating with the periphery unit. Accordingly, this often requires a manufacturer to ship a device with multiple versions of the device driver installation program on removable delivery media or, alternatively, load the various versions within the driver libraries of the operating systems, or upload the versions onto network servers for retrieval and installation. This adds to the cost of the peripheral by having to write an installation program for other host and Operating Systems (such as Linux or Mac).

Of course, there are instances when no driver software is required to be loaded to a host system, but other applications. For example, a DSL modem is currently designed to communicate with a host natively. After the modem is connected a user may want to have a program specific to that modem available to him, like remote administration. In such an instance, such programs are provided in removable delivery medium such as a CD-ROM (or must be downloaded from a website), with the same conventional problems mentioned above.

Accordingly, in light of the current state of the art and the drawbacks to current systems and methods for delivery of device software, a need exists for a system and a method for automatic delivery and launch for a software payload without user intervention or complex installation programs, and wherein the software payload and the device to which the payload belongs are paired.

### BRIEF SUMMARY OF THE INVENTION

One aspect of the present invention provides a method for delivery of software payload from a device to a host system, comprising the acts of

using an electronic component associated with the device;

configuring the electronic component to comprise a file system that is native to operating systems, which the host system can recognize, access, and use automatically for initiating communications with the device;

providing a primary file within the file system, with the primary file containing information that enables the host system for automatically taking action upon connection of the device with the host system; and

providing a secondary file pointed to by the primary file, with the secondary file having a set of executable commands that are executed by the host system for delivery of software payload from the electronic component associated with the device to the host system.

One optional aspect of the present invention provides a method for delivery of software payload from a device to a host system, wherein:

the electronic component is a memory contained within the device.

Another optional aspect of the present invention provides a method for delivery of software payload from a device to a host system, wherein:

the electronic component is a programmed chip comprising the file system.

Yet another optional aspect of the present invention provides a method for delivery of software payload from a device to a host system, wherein: the electronic component is a fixed storage unit of the device.

Still another optional aspect of the present invention provides a method for delivery of software payload from a device to a host system, wherein: the fixed storage unit is formatted to the file system that is recognized by the host system.

A further optional aspect of the present invention provides a method for delivery of software payload from a device to a host system, wherein: the file system is configured as a read only memory, containing a self-executing file.

Yet a further optional aspect of the present invention provides a method for delivery of software payload from a device to a host system, wherein: the file system is a CD File System Read-Only-Memory (CDFS).

Still a further optional aspect of the present invention provides a method for delivery of software payload from a device to a host system, wherein: the primary file includes at least partial information related to one or more contents of an *.INF file, accessed by the host system.

Another optional aspect of the present invention provides a method for delivery of software payload from a device to a host system, wherein: the secondary file is comprised of a series of commands that are executed in sequence, and which are grouped as a batch within the secondary file.

Yet another optional aspect of the present invention provides a method for delivery of software payload from a device to a host system, wherein: a connection between the device and the host system is through a peripheral interface using standard protocols for data transfer.

Still another optional aspect of the present invention provides a method for delivery of software payload from a device to a host system, wherein: the peripheral interface is a link, using the standard protocols for data transfer.

A further optional aspect of the present invention provides a method for delivery of software payload from a device to a host system, wherein: a component of the software payload is used by the host system for communicating with the device, and includes a set of commands that are executed for settings that are needed for the host system to recognize the device.

Still a further optional aspect of the present invention provides a method for delivery of software payload from a device to a host system, wherein: the method of delivery further includes a launching of the software payload within the host system.

Another aspect of the present invention provides a method for delivery of software payload that includes at least one software component that is used for allowing a host system to recognize and communicate with a device, comprising the acts of:

coupling the device with the host system, with the host system:

detecting the presence of the device;

determining the existence of at least one software component of the software payload within the host system,

if it is determined that the at least one software component of the software payload does not exists within the host system:

accessing an electronic component of the device,

recognizing and reading a file system within the electronic component;

retrieving the software payload from the electronic component by executing a primary file system within the electronic component that includes the software payload, and

installing software payload.

Still another aspect of the present invention provides a system for delivery of software payload from a device to a host system, comprising:

the device having an electronic component that is configured to comprise a file system that is native to the operating system of the host system, which the host system can recognize, access, and use automatically for initiating communications with the device;

the electronic component comprising a primary file within the file system, with the primary file containing information that enables the host system for automatically taking appropriate action upon connection of the device with the host system; and

the primary file pointing to a secondary file, with the secondary file having a set of executable commands that are executed by the host system for delivery of software payload from the electronic component of the device to the host system.

A further aspect of the present invention provides a system for delivery of software payload from a device to a host system, comprising:

the device having an electronic component that is configured to comprise a file system that is native to the operating system of the host system, which the host system can recognize, access, and use automatically for initiating communications with the device;

the electronic component comprising a primary file within the file system, with the primary file containing information that enables the host system for automatically taking appropriate action upon connection of the device with the host system; and

the primary file pointing to a secondary file, with the secondary file having a set of executable commands that are executed by the host system for delivery of the software payload from the electronic component of the device to the host system;

the device coupled with the host system, with the host system detecting the presence of the device, and determining the existence of at least one software component of the software payload within the host system;
if it is determined that the at least one software component of the software payload does not exist within the host system, the host system accessing the electronic component of the device, and reading the file system within the electronic component for retrieving the software payload from the electronic component by executing the primary file system containing the software payload for installing the software payload.

These and other features, aspects, and advantages of the invention will be apparent to those skilled in the art from the following detailed description of preferred non-limiting exemplary embodiments, taken together with the drawings and the claims that follow.

### BRIEF DESCRIPTION OF THE DRAWINGS

It is to be understood that the drawings are to be used for the purposes of exemplary illustration only and not as a definition of the limits of the invention. Throughout the disclosure, the word “exemplary” is used exclusively to mean “serving as an example, instance, or illustration.” Any embodiment described as “exemplary” is not necessarily to be construed as preferred or advantageous over other embodiments.

Referring to the drawings in which like reference character(s) present corresponding parts throughout:

FIG. 1 is an exemplary block diagram depicting the components of a host system and a device in accordance with the present invention;

FIG. 2 is an exemplary flowchart diagram for a method of enabling device of FIG. 1 to be recognized, accessed, and used by the host system of FIG. 1 in accordance with the present invention; and

FIG. 3 is an exemplary flowchart showing the method of delivery of software payload from the device of FIG. 1 to the host system of FIG. 1, when the host system is in communication with the device in accordance with the present invention.

### DETAILED DESCRIPTION OF THE INVENTION

The detailed description set forth below in connection with the appended drawings is intended as a description of presently preferred embodiments of the invention and is not intended to represent the only forms in which the present invention may be constructed and or utilized.

For purposes of illustration, programs and other executable program components are illustrated herein as discrete blocks, although it is recognized that such programs and components may reside at various times in different storage components, and are executed by the data processor(s) of the computers.

This disclosure refers throughout to the term “software payload,” or “payload,” which the present invention defines as necessary software or files needed to communicate with the host operating system and/or any software that is placed onto the device, and which is to be delivered to the host system. Non-limiting examples of software payload may include device drivers and/or other software applications. Non-limiting examples of other software applications within the payload may include any other type of file the manufacturer decides to load automatically, including HTML pages that direct the host to the manufacturers website, or any file that has any executable code. As one non-limiting example, the payload may include software that enables a user to “register” a device (e.g., a newly purchased printer) via a web link.

This disclosure refers throughout to the terms “driver,” “device driver,” “driver software,” “device driver software,” or the like, which the present invention defines as software or software programs (as part of possible payload) that a host system uses to communicate with a device (internal or external). In particular, a driver is generally defined as a software program that includes a set of commands (programming instructions), when executed, changes settings that are needed for the host system to recognize and communicate with a device. Therefore, a payload can include a device driver and/or other software applications or programs, but does not include an installation program for drivers or other applications because it is no longer needed.

Further, and for the sake of convenience and clarity, this disclosure refers throughout to the term device (periphery, periphery device or source system), the non-limiting examples of which may include a piece of hardware (e.g., printer, modem, etc.) that may reside internal or external of the host system (or destination system). Non-limiting examples of host systems (which themselves may be a device to other host or destination systems) may include a Personal Computer (PC), handheld devices such as Personal Digital Assistance (PDA), communication units such as cellular telephone, etc. Other non-limiting examples of related applications that will benefit from this invention are DSL modems, Network Attached Storage, Storage Area Network, camcorders, toys, games, and any type of peripheral that connects to a computer by any means.

The present invention provides for a method and system for automatically delivering software payload from a peripheral device to a host. For example, the present invention can load drivers from a device to a host system, and establish communication between the host and the device. In addition, the present invention can load other software (not drivers) automatically to the host as part of the overall software payload. For example, the present invention can load a remote administration program for a DSL modem automatically without user intervention, or the need to load a driver. Of course, the present invention can also load a driver and a software program as part of the overall payload being delivered. In addition to the delivery of software payload, the present invention can also launch the delivered payload within the host. The present invention eliminates installation programs, enabling a manufacturer of the periphery device to easily configure settings for any operating systems within the payload of software. In addition, this invention eliminates the need to shut down other software when loading the payload software from device to the host because it eliminates the installation program that generally requires access to shared resources within the host.

The method and system of the present invention uses an electronic component associated with the device (or provides one if none exists), and configures the electronic component to comprise a file system and files that are native to operating system of the host, which the host system can recognize, access, and use automatically for initiating communications with the device, and delivery of software payload and optional launching thereof. Hence, the present invention enables a peripheral device to automatically establish communication with a host, deliver a software payload to the host system, and optionally launch the delivered payload within the host.

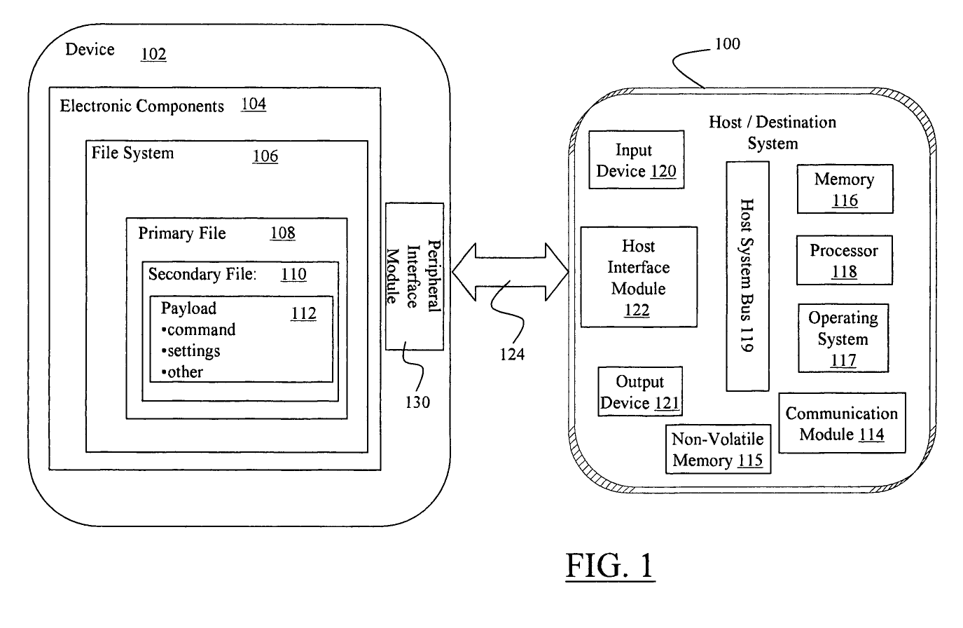

As best illustrated in FIG. 1, the present invention provides an automated delivery of a software payload 112 from a device 102 to a host system 100. That is, the software payload 112 of present invention enables the device 102 to automatically communicate with the host system 100, and deliver the software payload 112 to the host system 100 without the device having or using a removable delivery media. The present invention further provides for an auto launch of the delivered software payload within the host system. For an example, a flash driver loaded with the software payload could couple with a Universal Serial Bus (USB) port, or any other media, and instantly install and launch a Virtual Private Network. In this instance, only the user with the flash device could use the software payload while the USB, or any other media, is connected to the computer.

FIG. 1 is an exemplary block diagram depicting the components of the host system 100 and the device 102, which are linked together via a linkage 124, using standard protocols for data transfer. In generally, the host system 100 is comprised of a processor 118 that is in communication via bus 119 with the various modules and components within the host system 100 in accordance with protocols of an operating system 117. In general, the operating system 117 resides on a non-volatile storage device 115, which may also include the BIOS that resides on a non-volatile memory device. The processor 118 may be a general-purpose computer processor or a specialized processor such as an Application Specific Integrated Circuit (ASIC).

As illustrated, the host system 100 is comprised of a host interface module 122 configured for receiving user input from an input device 120 such as a keyboard, a mouse, or any other device 102 (internal or external) possibly via a peripheral interface module 130. The host interface module 122 may include multiple “ports” for receiving and transmitting data and user input/output, and may also be configured to receive and transmit information from and or to other remote devices using wired or wireless connections via a communication module 114. In addition, the host interface module 122 is further configured for outputting of information to the user, possibly through an output device 121 via an exemplary video display. The data or information from the host interface module 122 may also be provided to other devices 102 (internal or external) or other programs, e.g., to other software modules, for use therein, possibly serving as a wired or wireless gateway to external databases or other processing devices or communications nodes via the peripheral interface module 130. As further illustrated in FIG. 1, the processor 118 is also in communication via bus 119 with a memory 116 to permit storage of data and software to be manipulated by commands to the processor 118, and with a communication module 114, which can be comprised of any well-known transceiver module, internal modem, or the like.

The linkage 124 between the host interface module 122 and the peripheral interface module 130 of other devices 102 (internal or external) may be accomplished by any well-known standard protocol for data transfer. Non-limiting examples of respective host and peripheral interface modules 122 and 130 that use standard protocols for communication and data transfer may include any popular industry standard links or ports that use cables, Universal Serial Bus (USB), parallel, fire wire, network, optical, wireless, or a combination thereof, etc.

The exemplary device 102 illustrated in FIG. 1 is comprised of any periphery device or source system, which may be internal or external to the host system 100, and generally includes one or more electronic components 104. In order to enable delivery of software payload 112 from the device 102 to the host system 100 via the peripheral interface module 130, the device 102 must either already include or be provided with the electronic component 104 that is capable of storing software payload 112. In addition, the host system 100 must recognize, access, and use the electronic component 104 to access the software payload 112 for retrieval via the peripheral interface module 130. Therefore, in one embodiment, the electronic component 104 (already included or being provided) is comprised of a memory and or a fixed storage unit of the device 102, which may be formatted to a file system or directory 106 that the operating system 117 of the host system 100 recognizes. The file system or directory 106 includes at least one primary file 108, a secondary file 110, and the software payload 112. In an alternative embodiment, the electronic component 104 is comprised of a programmed chip of the device 102 that includes the file system or directory 106 that is recognized by the operating system 117, including the primary file 108, the secondary file 110, and software payload 112. It should be noted that the electronic component (e.g., memory, programmed chip or the like) and the software payload can be manufactured separately, and delivered to a device manufacture for installation therein.

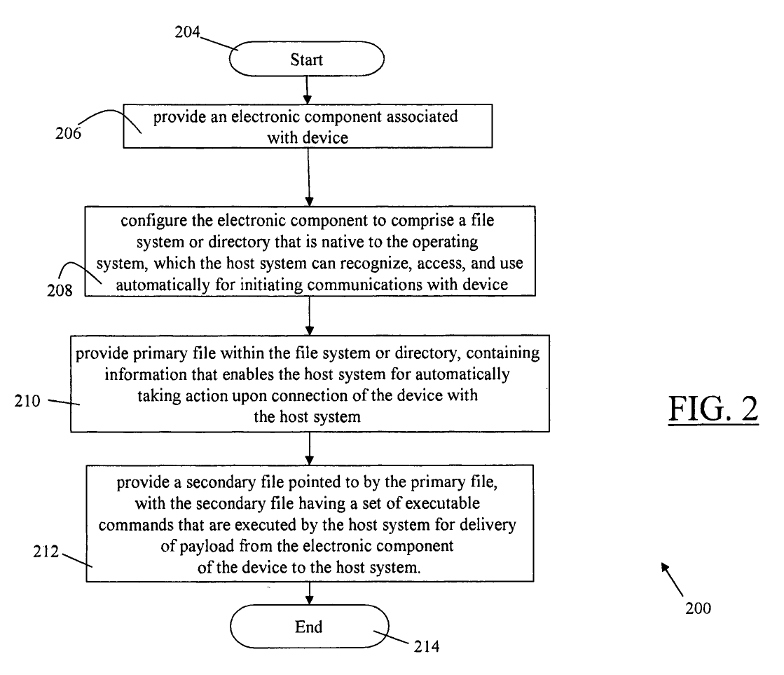

FIG. 2 is an exemplary flowchart diagram for a method of enabling the electronic component 104 of the device 102 to be recognized, accessed, and used by the host system 100. With the enabling method illustrated in FIG. 2, and described below, the software payload 112 is installed onto the host system 100 from the device 102, without a setup file (e.g., setup.exe), user intervention, or installation programs.

As illustrated in FIGS. 1 and 2, for delivery of payload 112 from the device 102 to the host system 100, in operation 206, the electronic component 104 of the device 102 is used by the present invention to store the payload 112 therein. This would eliminate the need to store the software payload 112 on a removable delivery media, or store it within the driver library of an operating system or use the Internet to store software payload 112. In other words, the device 102 and its software payload 112 are paired.

As further illustrated FIG. 2, in operation 208, the electronic component 104 is configured to comprise a file system or directory 106 that is native to the operating system 117 of the host system 100. Therefore, the host system 100 is able to recognize, access, and use the electronic component 104 for automatically initiating communications with the device 102. If the electronic component 104 is a memory or a fixed storage unit, the configuration process entails the well-known method of formatting the electronic component 104 so that the operating system 117 of the host system 100 can recognize, access (read), and use (execute) files within the file system or directory 106. If the electronic component 104 is a programmed chip, the programming of the chip should result in a file system or directory 106 that is recognized, accessed (read), and used (executed) by the operating system 117. In one embodiment, the file system 106 is configured as a read only memory, containing a self-executing file such as the primary file 108. A non-limiting example for the file system 106 with a read only memory file system is a CD File System Read-Only-Memory (CDFS-ROM), which is recognized by most of today's operating systems.

As further illustrated, in the operation 210, the electronic component 104 is further provided with a primary file 108 within the file system or directory 106, with the primary file 108 containing information that enables the host system 100 for automatically taking appropriate action upon connection of the device 102 with the host system 100. At operation 212, the primary file 108 is made to generally include or point to a secondary file 110, with the secondary file 110 having a set of executable commands that are executed by the host system 100 for delivery of software payload 112 from the electronic component 104 of the device 102 to the host system 100.

As stated above, most of today's operating systems use a removable delivery media (such as an optical media for example a CD) for recognizing and loading applications via a USB connection (such as the CDFS-ROM, mentioned above). In general, the file system or directory 106 in combination with the primary file 108 of the present invention are configured for signaling the operating system 117 of the host system 100 that the medium (the electronic component 104), which the software payload 112 reside on and is to be delivered from is an “automated run media.” A non-limiting example of an automated run media is an AUTORUN.INF file found on most of today's removable delivery media, which are easily recognized by most operating systems. The method of FIG. 2 of the present invention enables today's operating systems to view (or perceive) the electronic component 104 as a “removable delivery media,” or a CDFS-ROM file system. In other words, the present invention makes the connection (the peripheral interface module 130) of the peripheral device 102 to look like a “CD-ROM” to the host system 100 because most of today's host systems only recognize a CDFS-ROM files, which are placed on the media, executing an exemplary “*.inf” file that points to an exemplary “*.bat” file that loads the desired payload software. Hence, the automated run file within the file system 106 generally contains information that enables the operating system 117 of the host system 100 to automatically initiate appropriate action, immediately upon connection of the device 102 with the host system 100. In one embodiment, the primary file 108 includes at least partial information related to one or more contents of an INF file, which is recognized and accessed by most of today's operating systems.

The secondary file 110 is pointed to by the primary file 108, with the secondary file 110 having one or more executable commands that are executed by the host system 100 for delivery of software payload 112 from the electronic component 104 associated with the device 102 to the host system 100. In general, the secondary file 110 is comprised of one or more commands that are executed in sequence, and which are grouped as a batch within the secondary file 110. These commands, along with appropriate protocols of the operating system 117, enable delivery or loading of the software payload 112 from the device 102 to the host system 100. The commands found in the secondary file may be as simple as a copy command that when executed by the operating system 117, copies all the files or the entire software payload 112 from the device 102 to the host system 100.

It should be noted that with the software payload delivery method of the present invention illustrated and described, there is no installation programs (the setup files GUI that the users use to interact with the device 102) to update the various registers (settings or file systems) of the operating system 117 to enable the host 100 to communicate with the device 102. The software payload 112 is installed onto the host system 100 from the device 102, without a setup file, user intervention, or device driver installation programs, and the registry (settings or file systems) of the operating system is updated automatically in accordance with the software payload 112 (in particular, in accordance with the device driver component of the software payload 112) and the operating system 117 protocols.

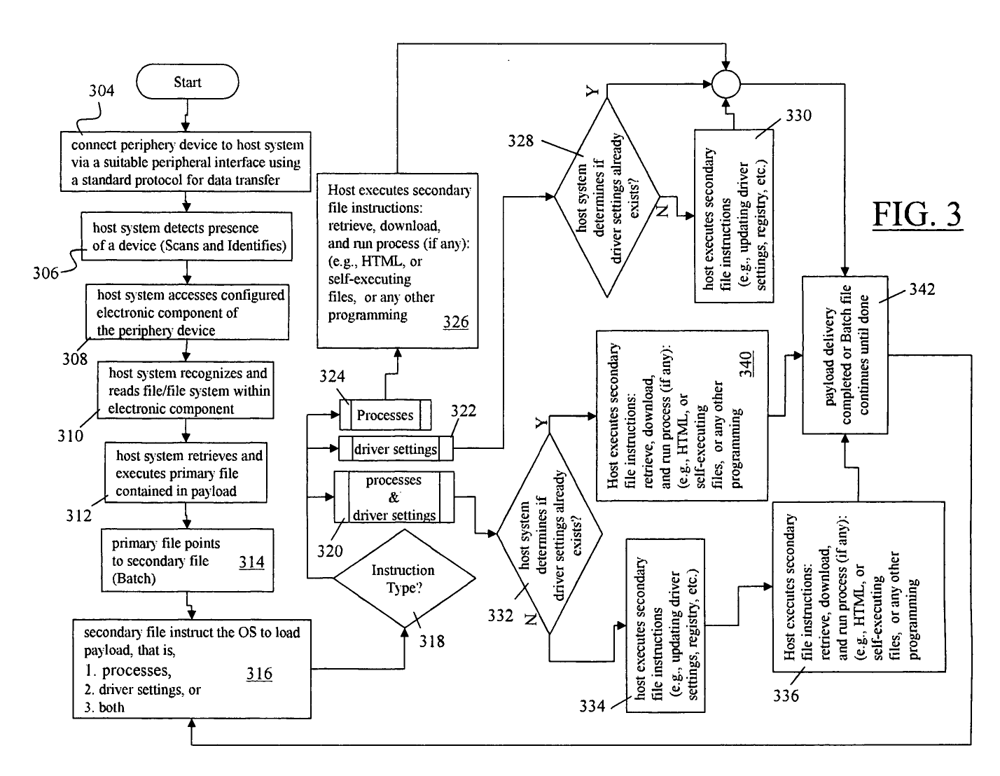

FIG. 3 is an exemplary flowchart showing the method of delivery of software payload 112 from a device 102 to a host system 100 when the host system 100 is in communication 124 with the device 102. As illustrated in FIGS. 1, and 3, at operation 304, the periphery device 102 is coupled with the host system 100 via a suitable peripheral interface 130 using a standard protocol for data transfer, a non-limiting example of which may include any popular industry standard links or ports that use cables, Universal Serial Bus (USB), parallel, fire wire, network, optical, wireless, or a combination thereof, etc. For example, the peripheral interface module 130 of the periphery device 102 may be a simple USB plug. In this instance, the peripheral device 102 is a USB peripheral device, with an electronic component 104 that is formatted in the CDFS file system 106 so that the USB peripheral device 102 appears to the operating system 117 of the host system 100 as a CD-ROM.

After the connection of the device 102 to the host 100, at operation 306, the host system 100 detects and identifies the presence of the device 102 by well-known methods such as scanning and identifying. At operation 308, the host system 100 accesses configured electronic component 104 of the periphery device 102, and at operation 310, the host system 100 recognizes and reads the file/file system 106 within the electronic component 104. That is, the host system 100 recognizes the file system 106 (non-limiting example, a CDFS) of the device 102, and perceives the USB peripheral as an exemplary CD-ROM. At operation 312, the operating system 117 of the host system 100 retrieves and executes the primary file 108 (non-limiting example, AUTORUN.INF) within electronic component 104, and at operation 314, the primary file 108 points to a secondary file 110 (non-limiting example, “*.bat”).

At operation 316, the secondary file 110 instructs the operating system 117 to load the payload software 112, which may include processes (e.g., programs or other software applications), driver settings, or both. That is, based on the type of instruction (determined by operation 318), only one of the operational acts 320, 322, or 324 will execute. It should be noted that the operations 318, 320, 322, and 324 are not actual operation acts, but are merely presented for clarity and better understanding for the flow of communication/data transfer between the host and the device. That is, the operations 318, 320, 322, and 324 do not represent an actual program or code that is executed. For example, if the secondary file 110 at operation 316 only has instructions to load processes and has no other commands or program instructions, then operation 326 will automatically execute. That is, there is no actual program or code represented by the flowchart operational act 318 that is coded that will be executed to determine the “instruction type” in the secondary file 110 (e.g., load processes), and then execute operation 324 (processes), and then execute operation 326. Accordingly, it is only for better understanding of the present invention in terms of the flow of communication/data transfer between the host and the device that the operational acts 318, 320, 322, and 324 are presented.

As illustrated, if the payload 112 includes only processes (e.g., programs or other software applications), then the secondary file 10 includes instructions to deliver the processes to the host system 100. In this instance, based on the instruction type 318, the host system 100 executes the instructions within the secondary file 10 to deliver the payload 112 (the processes 324). That is, the operational act 326 is executed, wherein the host system 100 retrieves, downloads, and executes instructions of the secondary file 110 to deliver other applications such as HTML files, or other self-executing files or programs.

As further illustrated, if the payload 112 includes only driver settings (e.g., periphery or device driver), then the secondary file 110 includes instructions to deliver the driver settings to the host system 100. In this instance, based on the instruction type 318, the host system 100 executes the instructions within the secondary file 110 to deliver the payload 112 (the driver settings 322). That is, the operational act 328 is executed, wherein the host system 100 retrieves, downloads, and executes instructions of the secondary file 110 to deliver driver settings to the host system 100 if one does not already exists. In other words, at operation 328, the host system 100 determines if a device driver (a component of the software payload 112) for the device 102 is already loaded within the host system 100. If none exists, at operation 330, the host 100 executes the secondary file 110 instructions for retrieval and download of driver component of the payload 112, and updates driver settings, registry, etc of the host system 100 in accordance with the secondary file 110 instructions. However, if at operation 328 it is determined that a driver setting already exists within the host 100, then the host system 100 will merely continue executing the remaining instructions of the secondary file 110 according to operation 342.

Finally, as illustrated, if the payload 112 includes processes and driver settings, then the secondary file 10 includes instructions to deliver processes and the driver settings to the host system 100. In this instance, based on the instruction type 318, the host system 100 executes the instructions within the secondary file 110 to deliver the payload 112 (the processes and driver settings 320). That is, the operational act 332 is executed, wherein the host system 100 retrieves, downloads, and executes instructions of the secondary file 110 to deliver processes and driver settings to the host system 100. In other words, at operation 332, the host system 100 determines if a device driver (a component of the software payload 112) for the device 102 is already loaded within the host system 100. If none exists, at operation 334, the host 100 executes the secondary file 110 instructions for retrieval and download of driver component of the payload 112, and updates driver settings, registry, etc of the host system 100 in accordance with the secondary file 110 instructions. In addition, the operational act 336 is executed, wherein the host system 100 retrieves, downloads, and executes instructions of the secondary file 110 to deliver other applications such as HTML files, or other self-executing files or programs. However, if at operation 332 it is determined that a driver setting already exists within the host 100, then the host system 100 will merely continue executing the remaining instructions of the secondary file 110, where the operational act 340 is executed, wherein the host system 100 retrieves, downloads, and executes instructions of the secondary file 110 to deliver other applications such as HTML files, or other self-executing files or programs. The operation 342 indicates that the host continues executing the programs instructions within the secondary file unit it is done.

It should be noted that the device driver as part of the overall payload 112 is used by the host system 100 for communicating with the device 102, and includes a set of commands that are executed for settings that are needed for the host system 100 to recognize and communicate the device 102. Further, after the driver is loaded (or if one already exists) and a communication is established between the host and the device, additional software can also be automatically delivered as part of the overall software payload 112 that would be of use to the host 100. In addition, in the case where no driver needs to be loaded, the software payload 112 can be automatically loaded onto the host computer, as described above.

Although the invention has been described in considerable detail in language specific to structural features and or method acts, it is to be understood that the invention defined in the appended claims is not necessarily limited to the specific features or acts described. Rather, the specific features and acts are disclosed as preferred forms of implementing the claimed invention. Therefore, while exemplary illustrative embodiments of the invention have been described, numerous variations and alternative embodiments will occur to those skilled in the art. Such variations and alternate embodiments are contemplated, and can be made without departing from the spirit and scope of the invention.

What is claimed is:

1. A method for delivery of software payload from a device to a host system, comprising the acts of:
using an electronic component associated with the device;
configuring the electronic component to comprise a file system that is native to operating systems, which the host system can recognize, access, and use automatically for initiating communications with the device;
providing a primary file within the file system, with the primary file containing information that enables the host system for automatically taking action upon connection of the device with the host system; and
providing a secondary file pointed to by the primary file, with the secondary file having a set of executable commands that are executed by the host system for delivery of software payload from the electronic component associated with the device to the host system.

2. The method for delivery of software payload from a device to a host system as set forth in claim 1, wherein:
the electronic component is a memory contained within the device.

3. The method for delivery of software payload from a device to a host system as set forth in claim 1, wherein:
the electronic component is a programmed chip comprising the file system.

4. The method for delivery of software payload from a device to a host system as set forth in claim 1, wherein:
the electronic component is a fixed storage unit of the device.

5. The method for delivery of software payload from a device to a host system as set forth in claim 4, wherein:
the fixed storage unit is formatted to the file system that is recognized by the host system.

6. The method for delivery of software payload from a device to a host system as set forth in claim 1, wherein:
the file system is configured as a read only memory, containing a self-executing file.

7. The method for delivery of software payload from a device to a host system as set forth in claim 1, wherein:
the file system is a CD File System Read-Only-Memory (CDFS).

8. The method for delivery of software payload from a device to a host system as set forth in claim 1, wherein:
the primary file includes at least partial information related to one or more contents of an *.INF file, accessed by the host system.

9. The method for delivery of software payload from a device to a host system as set forth in claim 1, wherein:
the secondary file is comprised of a series of commands that are executed in sequence, and which are grouped as a batch within the secondary file.

10. The method for delivery of software payload from a device to a host system as set forth in claim 1, wherein:
a connection between the device and the host system is through a peripheral interface using standard protocols for data transfer.

11. The method for delivery of software payload from a device to a host system as set forth in claim 10, wherein:
the peripheral interface is a link, using the standard protocols for data transfer.

12. The method for delivery of software payload from a device to a host system as set forth in claim 1, wherein:
a component of the software payload is used by the host system for communicating with the device, and includes a set of commands that are executed for settings that are needed for the host system to recognize the device.

13. The method for delivery of software payload from a device to a host system as set forth in claim 1, wherein:
the method of delivery further includes a launching of the software payload within the host system.

14. A method for delivery of software payload that includes at least one software component that is used for allowing a host system to recognize and communicate with a device, comprising the acts of:
coupling the device with the host system, with the host system:
detecting the presence of the device;
determining the existence of at least one software component of the software payload within the host system;
if it is determined that the at least one software component of the software payload does not exists within the host system:
accessing an electronic component of the device;
recognizing and reading a file system within the electronic component;
retrieving the software payload from the electronic component by executing a primary file system within the electronic component that includes the software payload; and
installing software payload.

15. The method for delivery of software payload that includes at least one software component that is used for allowing a host system to recognize and communicate with a device as set forth in claim 14, wherein:
the electronic component is a memory contained within the device.

16. The method for delivery of software payload that includes at least one software component that is used for allowing a host system to recognize and communicate with a device, as set forth in claim 16, wherein:
the memory is formatted to the file system that is recognized by the host system.

17. The method for delivery of software payload that includes at least one software component that is used for allowing a host system to recognize and communicate with a device as set forth in claim 15, wherein:
the electronic component is a programmed chip of the device comprising the file system.

18. The method for delivery of software payload that includes at least one software component that is used for allowing a host system to recognize and communicate with a device as set forth in claim 15, wherein:
the electronic component is a fixed storage unit of the device.

19. The method for delivery of software payload that includes at least one software component that is used for allowing a host system to recognize and communicate with a device as set forth in claim 19, wherein:
the fixed storage unit is formatted to the file system that is recognized by the host system.

20. The method for delivery of software payload that includes at least one software component that is used for allowing a host system to recognize and communicate with a device, as set forth in claim 15, wherein:
the file system is configured as a read only memory, containing a self-executing file.

21. The method for delivery of software payload that includes at least one software component that is used for allowing a host system to recognize and communicate with a device as set forth in claim 15, wherein:
the file system is a CD File System Read-Only-Memory.

22. The method for delivery of software payload that includes at least one software component that is used for allowing a host system to recognize and communicate with a device as set forth in claim 15, wherein:
the primary file includes at least partial information related to one or more contents of an INF file, accessed by the host system.

23. The method for delivery of software payload that includes at least one software component that is used for allowing a host system to recognize and communicate with a device as set forth in claim 15, wherein:
a secondary file is pointed to by the primary file, the secondary file is comprised of a series of commands that are executed by the host system in sequence, and which are grouped as a batch within the secondary file.

24. The method for delivery of software payload that includes at least one software component that is used for allowing a host system to recognize and communicate with a device as set forth in claim 15, wherein:
the act of coupling is comprised of a connection between the device and the host system is through a peripheral interface using standard protocols for data transfer.

25. The method for delivery of software payload that includes at least one software component that is used for allowing a host system to recognize and communicate with a device as set forth in claim 25, wherein:
the peripheral interface is a link, using the standard protocols for data transfer.

26. The method for delivery of software payload that includes at least one software component that is used for allowing a host system to recognize and communicate with a device as set forth in claim 15, wherein:
the at least one software component is used by the host system for communicating with the device, and includes a set of commands that are executed for settings that are needed for the host system to recognize the device.

27. The method for delivery of software payload that includes at least one software component that is used for allowing a host system to recognize and communicate with a device as set forth in claim 15, wherein:
the method of delivery further includes a launching of the software device within the host system.

28. A system for delivery of software payload from a device to a host system, comprising:
the device having an electronic component that is configured to comprise a file system that is native to the operating system of the host system, which the host system can recognize, access, and use automatically for initiating communications with the device;
the electronic component comprising a primary file within the file system, with the primary file containing information that enables the host system for automatically taking appropriate action upon connection of the device with the host system; and
the primary file pointing to a secondary file, with the secondary file having a set of executable commands that are executed by the host system for delivery of software payload from the electronic component of the device to the host system.

29. The system for delivery of software payload from a device to a host system as forth in claim 29, wherein:
the electronic component is a memory of the device.

30. The system for delivery of software payload from a device to a host system as forth in claim 29, wherein:
the electronic component is a storage device that is formatted to the file system that is recognized by the host system.

31. The system for delivery of software payload from a device to a host system as forth in claim 29, wherein:
the electronic component is a memory chip of the device comprising the file system.

32. The system for delivery of software payload from a device to a host system as forth in claim 29, wherein:
the electronic component is a fixed storage unit of the device.

33. The system for delivery of software payload from a device to a host system as forth in claim 32, wherein:
the fixed storage unit is formatted to the file system that is recognized by the host system.

34. The system for delivery of software payload from a device to a host system as forth in claim 29, wherein:
the file system is configured as a read only memory, containing a self-executing file.

35. The system for delivery of software payload from a device to a host system as forth in claim 29, wherein:
the file system is a CGD File System Read-Only-Memory.

36. The system for delivery of software payload from a device to a host system as forth in claim 29, wherein:
the primary file is the AUTORUN.INF file that includes at least partial information related to one or more contents files.

37. The system for delivery of software payload from a device to a host system as forth in claim 29, wherein:
the secondary file is comprised of a series of commands that are executed in sequence, and which are grouped as a batch within the secondary file.

38. The system for delivery of software payload from a device to a host system as forth in claim 29, wherein:
the connection between the device and the host system is through a peripheral interface using standard protocols for data transfer.

39. The A system for delivery of software payload from a device to a host system as forth in claim 38, wherein:
the peripheral interface is a link, using the standard protocols for data transfer.

40. The system for delivery of software payload from a device to a host system as forth in claim 29, wherein:
the software payload is comprised of a software component that is used by the host system for communicating with the device, and includes a set of commands that are executed for settings that are needed for the host system to recognize the device.

41. The system for delivery of software payload from a device to a host system as forth in claim 29, wherein:
the system for delivery of software further includes a launching of the software device within the host system.

42. A system for delivery of software payload from a device to a host system, comprising:
the device having an electronic component that is configured to comprise a file system that is native to the operating system of the host system, which the host system can recognize, access, and use automatically for initiating communications with the device,
the electronic component comprising a primary file within the file system, with the primary file containing information that enables the host system for automatically taking appropriate action upon connection of the device with the host system; and
the primary file pointing to a secondary file, with the secondary file having a set of executable commands that are executed by the host system for delivery of the software payload from the electronic component of the device to the host system;
the device coupled with the host system, with the host system detecting the presence of the device, and determining the existence of at least one software component of the software payload within the host system;
if it is determined that the at least one software component of the software payload does not exist within the host system, the host system accessing the electronic component of the device, and reading the file system within the electronic component for retrieving the software payload from the electronic component by executing the primary file system containing the software payload for installing the software payload.

43. The system for delivery of software payload from a device to a host system as forth in claim 42, wherein:
the electronic component is a memory of the device.

44. The system for delivery of software payload from a device to a host system as forth in claim 43, wherein:
the memory is formatted to the file system that is recognized by the host system.

45. The system for delivery of software payload from a device to a host system as forth in claim 43, wherein:
the electronic component is a storage chip of the device comprising the file system.

46. The system for delivery of software payload from a device to a host system as forth in claim 43, wherein:
the electronic component is a fixed storage unit of the device.

47. The system for delivery of software payload from a device to a host system as forth in claim 46, wherein:
the fixed storage unit is formatted to the file system that is recognized by the host system.

48. The system for delivery of software payload from a device to a host system as forth in claim 43, wherein:
the file system is configured as a read only memory, containing a self-executing file.

49. The system for delivery of software payload from a device to a host system as forth in claim 43, wherein:
the file system is a CD File System Read-Only-Memory.

50. The system for delivery of software payload from a device to a host system as forth in claim 43, wherein:
the primary file is an autorun.inf and points to one or more files.

51. The system for delivery of software payload from a device to a host system as forth in claim 43, wherein:
the secondary file is comprised of a series of commands that are executed in sequence, and which are grouped as a batch within the secondary file.

52. The system for delivery of software payload from a device to a host system as forth in claim 43, wherein:
the connection between the device and the host system is through a peripheral interface using standard protocols for data transfer.

53. The system for delivery of software payload from a device to a host system as forth in claim 43, wherein:
the peripheral interface is a link, using the standard protocols for data transfer.

54. The system for delivery of software payload from a device to a host system as forth in claim 43, wherein:
the at least one software component of the software payload is used by the host system for communicating with the device, and includes a set of commands that are executed for settings that are needed for the host system to recognize the device.

55. The system for delivery of software payload from a device to a host system as forth in claim 43, wherein:
the system for delivery of software further includes a launching of the software device within the host system.
